(19) United States
(12) Patent Application Publication
(10) Pub. No.: US 2026/0095149 A1
(43) Pub. Date: Apr. 2, 2026

(54) ACOUSTIC RESONATOR AND FILTER DEVICE WITH SERIES DIELECTRIC CAPACITOR

(71) Applicant: Murata Manufacturing Co., Ltd., Nagaokakyo-shi (JP)

(72) Inventors: Kurt RAIHN, Grass Valley, CA (US); James R. COSTA, Lompoc, CA (US); Sean MCHUGH, Santa Barbara, CA (US)

(21) Appl. No.: 19/340,237

(22) Filed: Sep. 25, 2025

Related U.S. Application Data
(60) Provisional application No. 63/701,013, filed on Sep. 30, 2024.

(51) Int. Cl. H03H 9/54; H03H 9/17; H03H 9/56

(52) U.S. Cl. CPC H03H 9/542; H03H 9/175; H03H 9/568

(57) ABSTRACT

A filter device is provided that includes a acoustic resonator having a substrate; a piezoelectric layer coupled to the substrate by one or more intermediate layers; and a conductor pattern on a surface of the piezoelectric layer, the conductor pattern including a pair of busbars having a plurality of interleaved fingers extending therefrom to form an interdigital transducer (IDT). The filter device further includes a dielectric capacitor electrically coupled in series to the acoustic resonator. The dielectric capacitor includes a dielectric layer on a surface of a first busbar of the pair of busbars and at least one metal layer on a surface of the dielectric layer, such that the dielectric layer is between the first busbar and the at least one metal layer to form the dielectric capacitor.

### CROSS REFERENCE TO RELATED APPLICATIONS

The current application claims priority to U.S. Patent Provisional Application No. 63/701,013, filed Sep. 30, 2024, the entire contents of which are hereby incorporated by reference.

### TECHNICAL FIELD

This disclosure relates to radio frequency filters using acoustic wave resonators, and, more specifically, to filters using capacitors in series with acoustic resonators for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band may depend on the specific application. For example, in some cases a “pass-band” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have broad impact on system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels.

Moreover, the desire for wider communication channel bandwidths will inevitably lead to the use of higher frequency communications bands. Radio access technology for mobile telephone networks has been standardized by the 3GPP (3rd Generation Partnership Project). Radio access technology for 5th generation mobile networks is defined in the 5G NR (new radio) standard. The 5G NR standard defines several new communications bands. Two of these new communications bands are n77, which uses the frequency range from 3300 MHz to 4200 MHz, and n79, which uses the frequency range from 4400 MHz to 5000 MHz. Bandpass filters for bands n77 and n79 must be capable of handling the transmit power of the communications device. However, current acoustic resonators have too much coupling for narrow bands, such as n79, and, thus, there is a need for improved filters that can operate at narrow frequency bands, while also improving the manufacturing processes for making such filters.

### SUMMARY

Accordingly, as described herein, an acoustic resonator and filter device incorporating the same is provided in which a capacitor is coupled in series with an acoustic resonator (e.g., an XBAR) to decrease the effective coupling of the resonator and to shift shifting resonance upwards in frequency.

Thus, according to an exemplary embodiment, a filter device is provided that includes a acoustic resonator including a substrate; a piezoelectric layer coupled to the substrate by one or more intermediate layers; and a conductor pattern on a surface of the piezoelectric layer, the conductor pattern including a pair of busbars having a plurality of interleaved fingers extending therefrom to form an interdigital transducer (IDT); and a dielectric capacitor electrically coupled in series to the acoustic resonator, the dielectric capacitor including a dielectric layer on a surface of a first busbar of the pair of busbars and at least one metal layer on a surface of the dielectric layer, such that the dielectric layer is between the first busbar and the at least one metal layer to form the dielectric capacitor.

In another exemplary aspect of the filter device, the first busbar is configured as a first electrode of the dielectric capacitor and the at least one metal layer is configured as a second electrode of the dielectric capacitor, such that the dielectric layer is sandwiched between the first and second electrodes.

In another exemplary aspect of the filter device, the at least one metal layer is further disposed on the surface of the piezoelectric layer, such that the at least one metal layer is substantially coplanar with the first busbar, and wherein a gap extends between the at least one metal layer and the first busbar in a planar view of the surface of the piezoelectric layer.

In another exemplary aspect of the filter device, the pair of busbars extend in a first direction and the interleaved fingers extend in a second direction that is substantially perpendicular to the first direction, and the gap extends in the first direction along a side surface of the first busbar that faces a side surface of the at least one metal layer. Moreover, the dielectric layer can be silicon oxide and is also disposed in the gap between the at least one metal layer and the first busbar.

In another exemplary aspect of the filter device, the at least one metal layer comprises a plurality of metal layers, and the at least one metal layer conforms to a shape of the dielectric layer in a plan view of the surface of the piezoelectric layer.

In another exemplary, the filter device includes an additional dielectric capacitor electrically coupled in series to the acoustic resonator, the additional capacitor including a dielectric layer on a surface of a second busbar of the pair of busbars and at least one metal layer on a surface of the dielectric layer opposite the second busbar to form the additional dielectric capacitor, such that the acoustic resonator is electrically coupled in series between the dielectric capacitor and the additional dielectric capacitor.

In another exemplary aspect of the filter device, a portion of the piezoelectric layer forms a diaphragm that is over a cavity that extends at least partially in the one or more intermediate layers, the one or more intermediate layers comprising silicon oxide or silicon dioxide, and the dielectric capacitor does not overlap the cavity in a plan view of the piezoelectric layer.

In another exemplary aspect of the filter device, the one or more intermediate layers comprise a Bragg mirror disposed between the piezoelectric layer and the substrate.

In another exemplary aspect of the filter device, the IDT is configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved fingers of the IDT.

In another exemplary, a filter device is provided that includes an acoustic resonator including a substrate; a piezoelectric layer coupled to the substrate by one or more intermediate layers; an interdigital transducer (IDT) on a surface of the piezoelectric layer, the IDT including a pair of busbars having a plurality of interleaved fingers extending therefrom; and a capacitor electrically coupled in series to the acoustic resonator and integrated as a portion of a first busbar of the pair of busbars, the capacitor and a pair of metal layers and a dielectric layer disposed therebetween.

In another exemplary aspect of the filter device, the pair of metal layers of the capacitor comprise a first busbar of the pair of busbars that is opposite the piezoelectric layer; and at least one metal layer on a surface of the dielectric layer that is opposite the first busbar.

In another exemplary aspect, the filter device includes an additional dielectric capacitor electrically coupled in series to the acoustic resonator, the additional capacitor integrated as a portion of a second busbar of the pair of busbars, the additional capacitor including a dielectric layer on a surface of a second busbar of the pair of busbars and at least one metal layer on a surface of the dielectric layer opposite the second busbar to form the additional dielectric capacitor, such that the acoustic resonator is electrically coupled in series between the dielectric capacitor and the additional dielectric capacitor.

In another exemplary aspect, a radio frequency module is provided that includes a filter device including a plurality acoustic wave resonators connected in parallel; and a radio frequency circuit coupled to the filter device, the filter device and the radio frequency circuit being enclosed within a common package. In this aspect, at least one acoustic wave resonator of the plurality of acoustic wave resonators of the filter device includes a substrate; a piezoelectric layer coupled to the substrate by one or more intermediate layers; and a conductor pattern on a surface of the piezoelectric layer, the conductor pattern including a pair of busbars having a plurality of interleaved fingers extending therefrom to form an interdigital transducer (IDT). Moreover, the filter device further includes a dielectric capacitor electrically coupled in series to the acoustic resonator, the dielectric capacitor including a dielectric layer on a surface of a first busbar of the pair of busbars and at least one metal layer on a surface of the dielectric layer, such that the dielectric layer is between the first busbar and the at least one metal layer to form the dielectric capacitor.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6A is a schematic view of a portion of a filter device that includes an acoustic resonator with a dielectric capacitor coupled in series according to an exemplary aspect.

FIG. 6B is a top plan view of the portion of the filter device shown in FIG. 6A.

FIG. 6C is another schematic view of the portion of the filter device shown in FIG. 6A according to an exemplary aspect.

FIG. 7 is a top plan view of a portion of a filter device that includes an acoustic resonator with a pair of dielectric capacitors coupled in series according to an exemplary aspect.

FIG. 8 is a chart of an admittance of a filter device with one or more acoustic resonators (e.g., XBARs) as a function of frequency with a dielectric capacitor couple in series according to an exemplary aspect.

FIG. 9A is a schematic view of a portion of a filter device that includes an XBAR with a dielectric capacitor coupled in series according to another exemplary aspect.

FIG. 9B is a detailed schematic view of the portion of the filter device shown in FIG. 9A.

FIG. 10A is a schematic view of a portion of a filter device that includes an acoustic resonator with a dielectric capacitor coupled in series according to another exemplary aspect.

FIG. 10B is a detailed schematic view of the portion of the filter device shown in FIG. 9A.

FIGS. 11A to 11C are charts of an admittance as a function of frequency of the filter device according to exemplary aspects.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

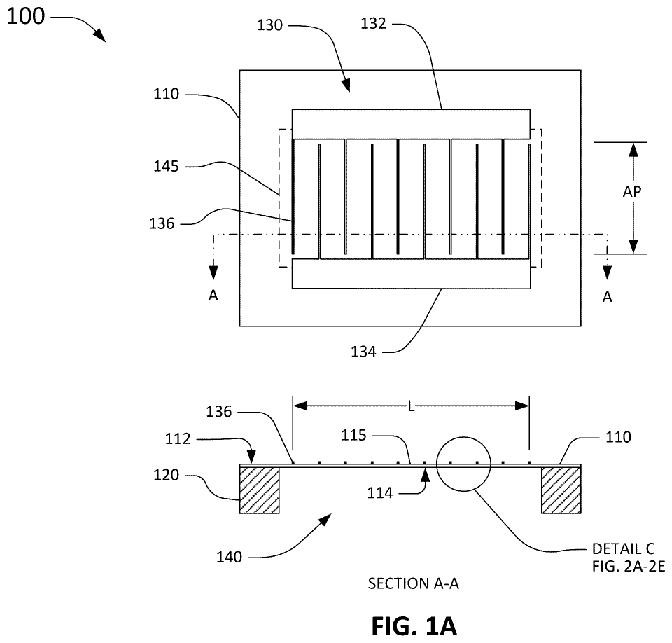

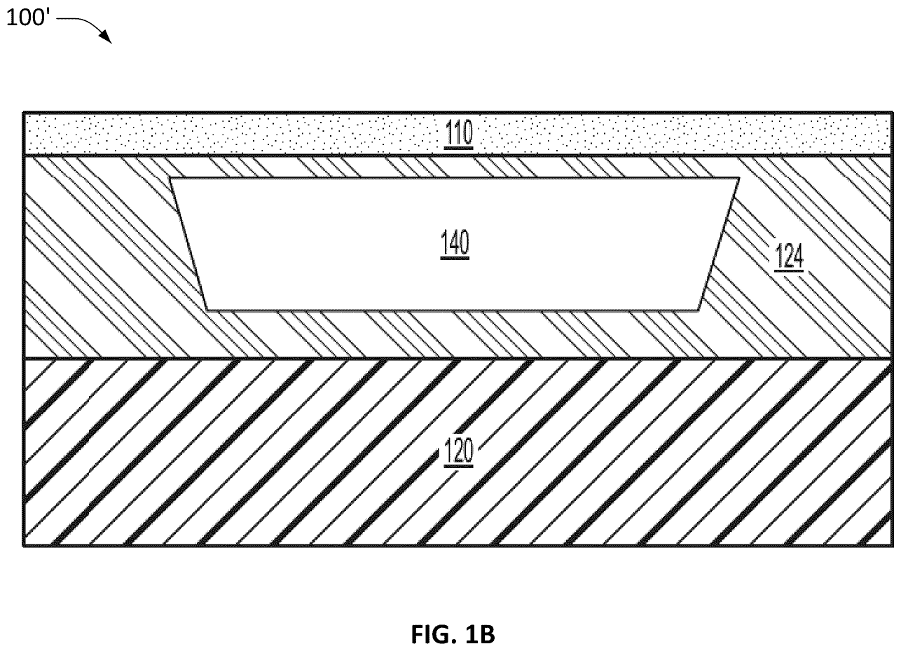

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90, 0) and (0, 128-90, 0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole entirely or partially within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

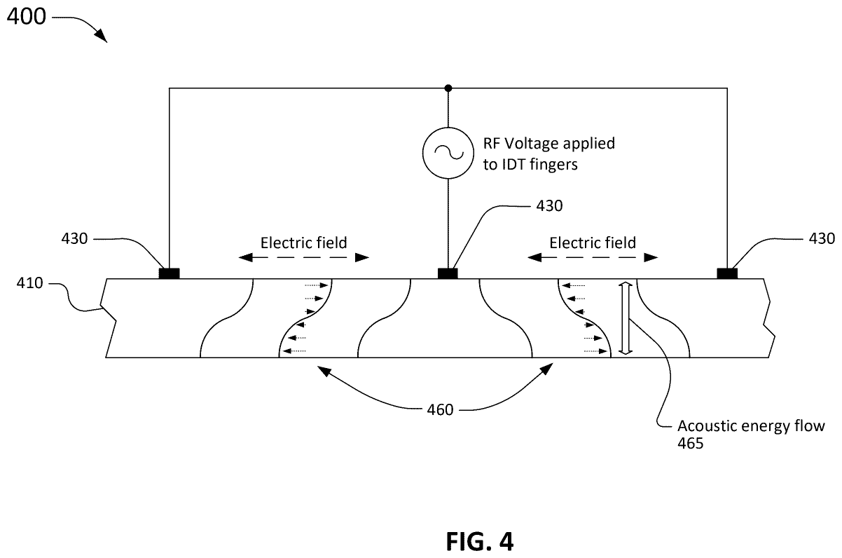

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

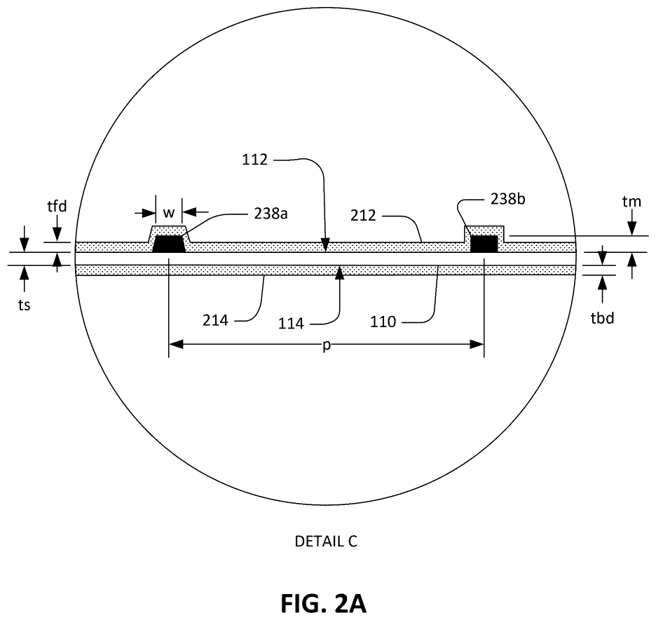

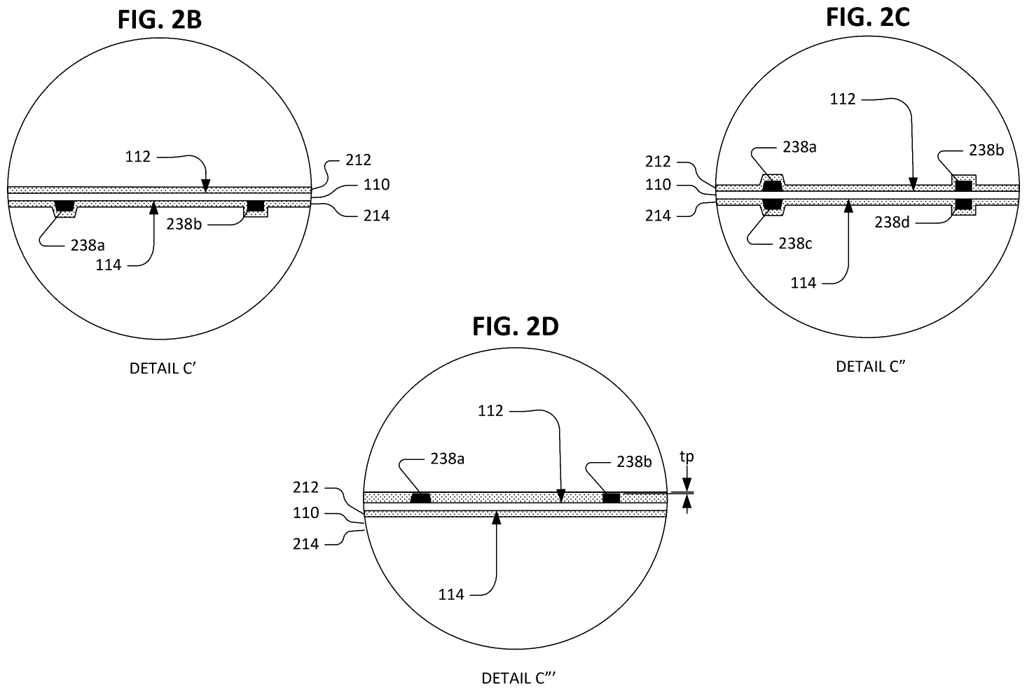

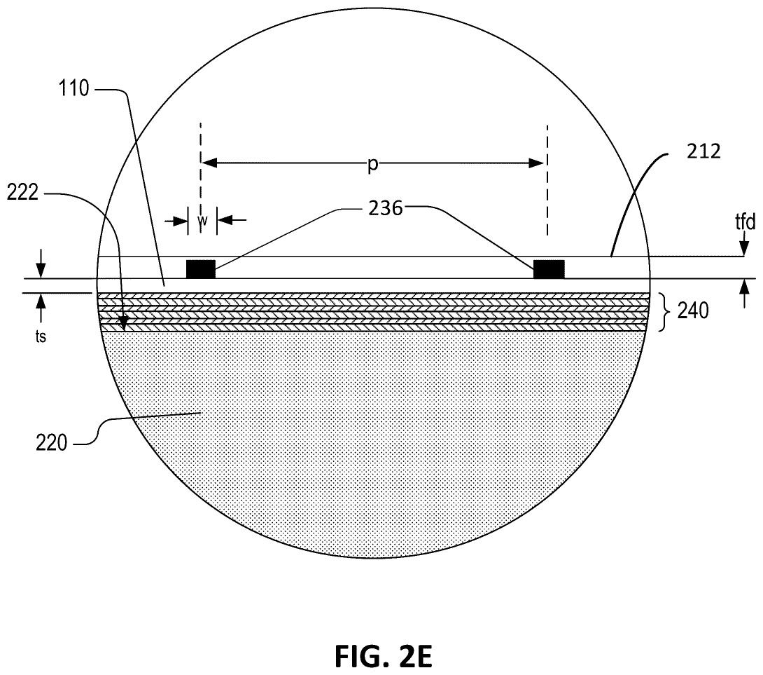

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 (also referred to as a Bragg mirror) is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon oxide, carbon-containing silicon oxide, aluminum and certain plastics such as cross-linked polyphenylene polymers. Materials having comparatively high acoustic impedance include hafnium oxide, silicon nitride, aluminum nitride, silicon carbide, tungsten carbide, tungsten carbide, tantalum carbide, rhenium oxide, chromium carbide silicide, niobium carbide, zinc carbide, zinc nitride, lanthanum boride, vanadium carbide, yttrium oxide, magnesium oxide, boron carbide, strontium fluoride, barium fluoride, tantalum oxide, tungsten oxide, hafnium nitride, tungsten nitride, platinum, tungsten, copper, gold, and silver. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

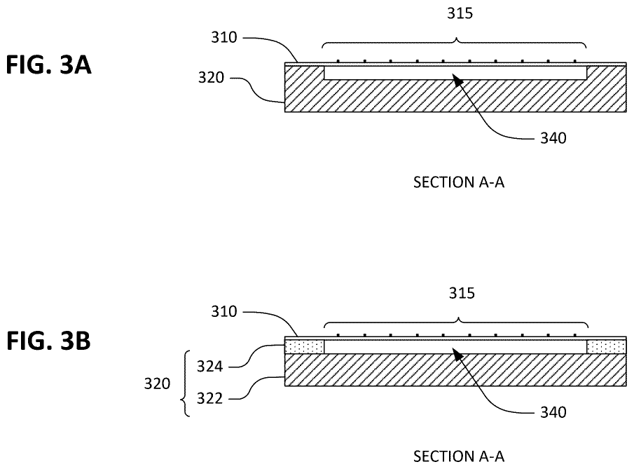

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

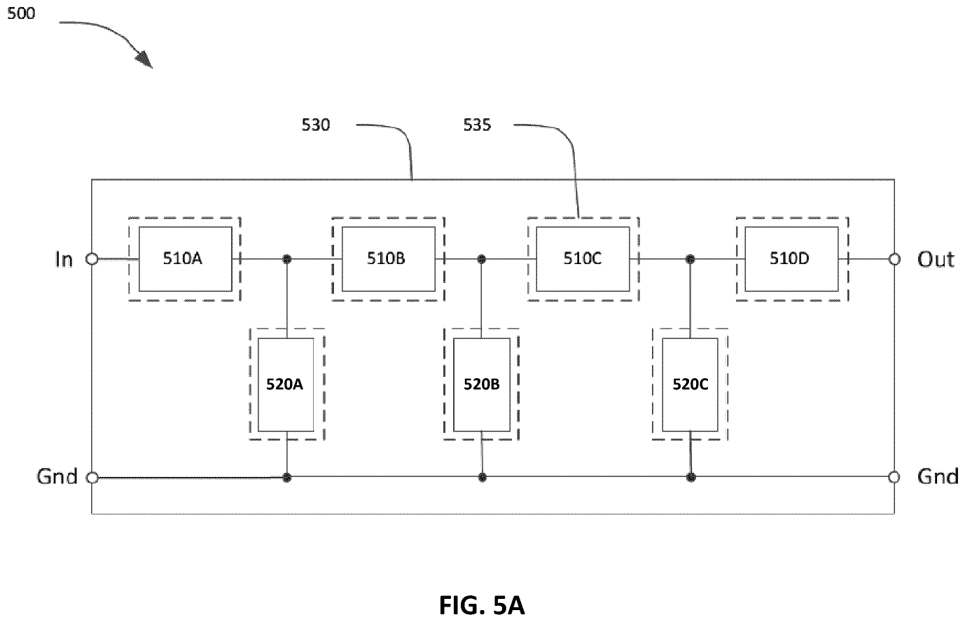

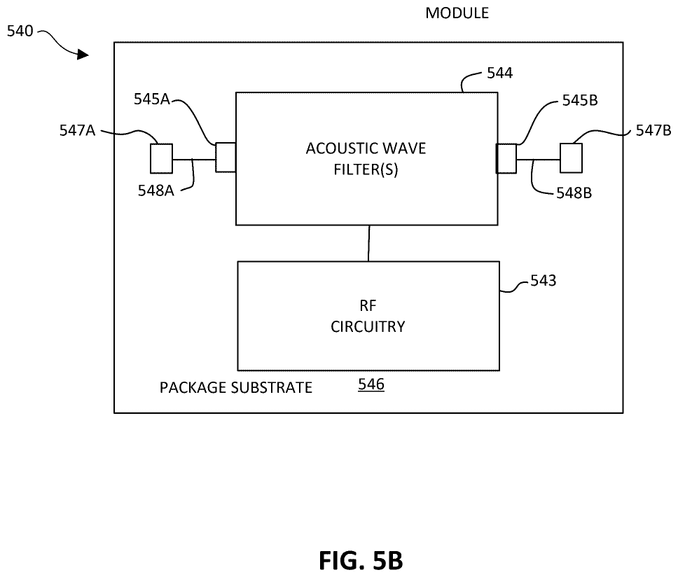

FIG. 5A is a schematic circuit diagram and layout for a high frequency bandpass filter 500 using a plurality of bulk acoustic wave resonators (e.g., XBARs), such as the general XBAR configuration 100 (e.g., the bulk acoustic wave resonators) described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate. Moreover, as will be described below, exemplary aspects include a resonator with a dielectric capacitor coupled in series thereto to shift the resonance frequence (e.g., shift upwards), while also reducing the coupling coefficient and enabling the design of a narrower band filters than existing configurations. Accordingly, the filter 500 can include one or a plurality of capacitors that are electrically coupled series to the plurality of IDTs, respectively, as will become apparent to those skilled in the art.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or radio frequency “RF” circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

As generally described above, existing electrical filters and resonators that are utilized in processing electrical signals are designed to permit specific signal frequencies (e.g., the passband) while obstructing or diminishing unwanted frequencies (e.g., the stopband). However, existing methodologies often necessitate diverse manufacturing techniques and materials to provide narrower surface acoustic wave (SAW) and/or bulk acoustic wave (BAW) type passband resonators, which leads to increased inventory requirements and additional qualification steps. Moreover, the varying electrical properties of these materials may jeopardize performance.

In view of these limitations, the exemplary aspects provide for the implementation of a dielectric capacitor coupled in series with an IDT of an acoustic resonator, such as an XBAR, SAW and/or BAW type resonator, that allows for the shifting upwards, for example, of the resonant frequency of the resonator and in turn allows for the design of narrower band filters without the complications of sourcing and qualifying new materials. Moreover, by leveraging existing materials and manufacturing methods, exemplary aspects of the present disclosure can provide a streamlined approach that not only enhances the design flexibility of filters but can also preserve or improve performance consistency across applications of such filter devices.

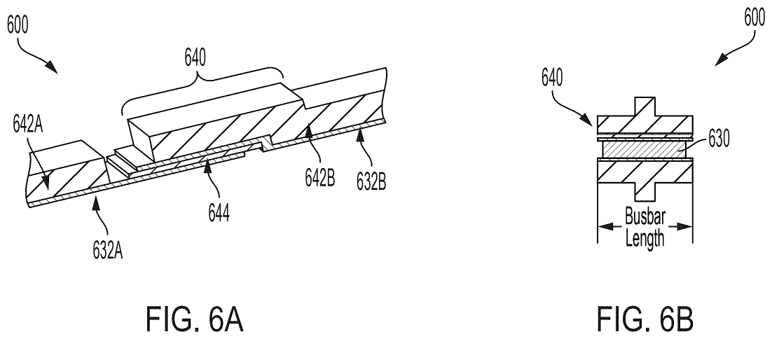

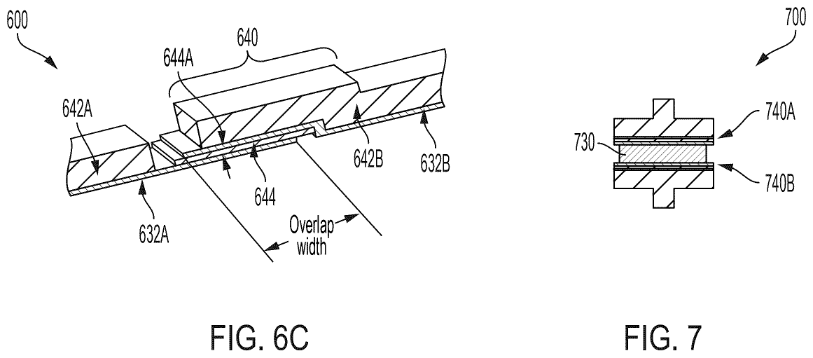

FIG. 6A is a schematic view of a portion of a filter device 600 that includes an acoustic resonator (e.g., an XBAR) with a dielectric capacitor 640 coupled in series according to an exemplary aspect. In general, the filter device 600 includes an acoustic resonator with a one or a pair of dielectric capacitors on one or both sides of the IDT of the acoustic resonator. The filter device 600 shown in FIGS. 6A-6C illustrates a series capacitor's integration on one side of the IDT. The series capacitor(s) is electrically coupled in series to the acoustic resonator (e.g., a bulk acoustic resonator) and can be integrated as at least a portion of one busbar (e.g., a first busbar) or as pair of busbars (e.g., first and second busbars) of the IDT of the acoustic resonator in an exemplary aspect.

As will be described in detail below, the series capacitor is generally formed from a pair of metal layers of the busbar and a dielectric layer disposed therebetween. In an alternative aspect, the series capacitor(s) can be formed separately from the one or more busbars or a wire line extending from the one or more busbars. In either case, the acoustic resonator can be an XBAR (e.g., a membrane based or solidly mounted XBAR as described herein). However, it should be appreciated that the dielectric capacitor configuration described herein and be implemented for other types of SAW or BAW resonators as would be appreciated to one skilled in the art.

Moreover, it is noted that while the series capacitor described herein can generally be considered a MIM (i.e., metal-insulator-metal) capacitor in the exemplary aspects, the series capacitor can be other types of capacitors in other exemplary aspects, such as one or a pair of interdigitated capacitors (IDCs). As described herein the capacitor can be coupled in series to the IDT of the acoustic resonator or a pair of capacitors can each be coupled in series with a respective busbar of the IDT as described herein. In other words, the IDT is between each of the capacitors (which can be a MIM capacitor or IDC). An IDC is generally configured as a multi-finger periodic structure that uses the capacitance that occurs across a narrow gap between conducting fingers. However, there are tradeoffs between which type of capacitor can be used according to exemplary aspects. More particularly, the IDC may be physically large depending on the amount of capacitance needed, and, thus, would likely take up more physical space in the layout, However, an IDC may have better tolerance (compared with a MIM capacitor structure) in regard to absolute capacitance because the M1 line widths can be very well controlled. As also described herein, the capacitor can be partially or entirely integrated with the busbar of the acoustic resonator according to an exemplary aspect.

In any event, as shown in the partial view in FIG. 6A, a portion of metal pattern (e.g., referred to as metal 1 or M1) forming a metal layer 632A is shown, in which the metal layer 632A can be a busbar that corresponds to one of the pair of busbars 132 and 134 as shown in FIG. 1A, for example. Thus, in this exemplary aspect, metal layer M1 is configured as a busbar 632A (or portion of the busbar) that corresponds to a portion of busbar 132. It is also noted that the busbars of the IDT, such as busbar 632A can more generally be considered as wire routing (e.g., one or more wire line) that connects the interleaved fingers of each resonator to the respective electric potentials applied across the area of the resonators and/or connecting different resonators of a filter to each other and/or to ground. Thus, in this aspect, the metal layer M1 can also be configured as wiring or a wire line of the acoustic resonator.

It is further noted that while the IDT is generally described as having interleaved fingers as shown in FIG. 1A as discussed above, the exemplary configuration can have alternate IDT configurations. For example, in alternative aspects, electrodes of the IDT with positive and negative potentials can be disposed on each side of the piezoelectric layer, similar to the configuration described above with respect to FIG. 2C. In yet another aspect, electrodes with positive and negative potentials can be disposed on one side of the piezoelectric layer while a floating electrode can be disposed on the other side of the piezoelectric layer. As such, the particular IDT configuration of the exemplary aspects should not be so limited.

In any event, a second metal pattern 642A (e.g., referred to as metal 2 or M2) can be disposed on a surface of busbar 632A when forming the acoustic resonator device. Accordingly, the metal layer M1 of the dielectric capacitor 640 can either be part of the busbar 632A in an exemplary aspect, or alternatively, can be a wire line or other metal layer extending from the busbar of the acoustic resonator. In the configuration shown in FIG. 6A, the dielectric capacitor 640 is integrated as part of the busbar that includes metal layer 632A and metal layer 632B with a dielectric layer 644 disposed therebetween. In other words, the metal layer M1 is formed from the metal layer 632A of the busbar of the acoustic resonator, but it is not so limited.

In either case, a dielectric capacitor 640 (also referred to as a series capacitor or simply a capacitor in this disclosure) is electrically coupled in series to the IDT of the acoustic resonator. In general, the dielectric capacitor 640 is a capacitor that is electrically coupled in series to the acoustic resonator and includes the dielectric layer 644 and a pair of metal layers on opposing surfaces of the dielectric layer 644 where the metal layers can form the anode and cathode of the capacitor, which is integrated as part of the busbar. In an exemplary aspect, the dielectric capacitor 640 is formed by a dielectric layer 644 being disposed on the metal pattern M1 forming the portion of the busbar 632A. Another metal layer 632B is then formed on the opposing surface of the dielectric layer 644 to sandwich the dielectric layer 644 therebetween. That is, metal layers 632A and 632B are disposed on opposing sides of dielectric layer 644. Effectively, metal layer 632A and metal layer 632B form first and second electrodes (e.g., a cathode and an anode, or also referred to as top and bottom electrodes) of the dielectric layer 644. One or more additional metal layers 642B can be disposed on metal layer 632B as further shown to adjust the thickness of the busbar. The one or more additional metal layers 642B are offset from the location of where metal layer 632B is disposed on dielectric layer 644. Moreover, the amount of series capacitance can be adjusted by modifying several parameters, such as the busbar width, the overlap length, the thickness of dielectric layer 644, and the area and thickness of the metal layers.

It is also noted that according to an exemplary aspect, the dielectric capacitor 640 does not overlap the perimeter (or edges) of the cavity of the acoustic resonator in an exemplary aspect. That is, when a dielectric capacitor 640 is implemented in a cavity-based acoustic resonator, such as that described above and shown in FIGS. 1A, 1B, 3A and 3B, for example, the dielectric capacitor 640 does not overlap the cavity 140/340 in the plan view of the piezoelectric layer 110/310, which is in the thickness direction of the acoustic resonator. Instead, the dielectric capacitor 640 is outside the cavity in the plan view and is formed from, inter alia, part or all of busbar 132 or 134, for example.

In yet another aspect, the dielectric capacitor 640 may be outside (i.e., not overlap in the plan view) the active area of the acoustic resonator, which can be considered the aperture of the IDT and the respective gaps between the ends of the interleaved fingers and opposing busbars. In some cases, the active area may be slightly larger than the aperture plus the respective gaps between ends of the interleaved fingers and opposing busbars to include an area equal to the aperture plus two times the distance of at least one of the gaps between ends of the interleaved fingers and opposing busbars. In another embodiment, the dielectric capacitor 640 can be as close to the active area as possible if it does not extend past the edge of a cavity of the resonator. This configuration can be implemented for both cavity-based acoustic resonators, such as that described above and shown in FIGS. 1A, 1B, 3A and 3B, and solidly-mounted acoustic resonators, such as that shown in FIG. 2E and described above. In such a case, the dielectric capacitor 640 is again formed by part or all of the respective busbar.

FIG. 6B is a top plan view of the portion of the filter device shown in FIG. 6A. As shown, the filter device 600 includes an IDT 630 of an acoustic resonator (e.g., an XBAR) coupled in series to dielectric capacitor 640, which is shown on one side of the IDT 630 of the acoustic resonator. As further shown, a wire line or other metal layer can be provided that is directly coupled and extends from an edge of one of the pair of busbars 132 and 134 as shown in FIG. 1A. Thus, the dielectric capacitor 640 can be formed with the wire line serving as an electrode thereof in an alternative aspect. It should also be appreciated that IDT 630 can correspond to IDT 130 of FIG. 1A with the dielectric capacitor 640 being electrically coupled in series by one of the busbars of the metal pattern forming IDT 630 (e.g., corresponding to IDT 130).

The busbar length is shown and can be adjusted according to the required configuration of the filter device 600. It should be appreciated that the busbar length can be the same length “L” as that of the IDT shown in FIG. 1A and described above. Alternatively, the busbar length can be longer than the length of the IDT, such as IDT 630 shown in FIG. 6B. As also described a wire line can be coupled to the busbar as described above and can be a separate component of which a portion or all of the wire lines can also be configured as one of the electrode layers of the dielectric capacitor described herein. In an exemplary aspect, the one or more busbars can be distinct from the wire line in that the busbar(s) can have at least a dimension that is different from the wire line, with the respective dimension (e.g., the busbar length of FIG. 6B) being substantially similar within the entire busbar. In other words, the busbar can have a shape with at least one dimension that is substantially similar (e.g., within manufacturing tolerances) as the wire line, but is otherwise different from a dimension of a shape of the wire line. For example, the wire line illustrated in FIG. 6B shows a portion protruding in a direction perpendicular to the length of the busbar in the plan view thereof. According to an exemplary aspect, one or more of the dielectric capacitors 640 is disposed between or substantially between (e.g., approximately or substantially midway with ±10% of the center) between IDTs 630 of adjacent resonators (it is noted that a single resonator 630 is shown in FIG. 6B). In this aspect, potential fabrication errors can be minimized during manufacturing of the ladder filter that includes a plurality of acoustic resonators as described herein (e.g., as shown in FIG. 5A) with one or more dielectric capacitors 640.

FIG. 6C is another schematic view of the portion of the filter device 600 shown in FIG. 6A according to an exemplary aspect. The components in FIG. 6C generally correspond to those described above with respect to FIG. 6A, except that the “overlap width” of the two opposing electrodes (i.e., metal layers 632A and 632B) of the dielectric capacitor 640 is shown as well as the thickness 644A of dielectric layer 644. As noted above, adjusting the parameters such as the “overlap width” and dielectric thickness 644A, can be used to set the capacitance of dielectric capacitor 640. FIG. 6C also illustrates the overlap between the busbar 632A and the dielectric layer 644, which can be silicon oxide or silicon dioxide, for example. Alternatively, a piezoelectric layer could be used as the dielectric layer 644 in an exemplary aspect. In either case and as also described above, the metal layer M1 (e.g., 632A and 632B) and the metal layer M2 (e.g., 642A and 642B) can also be configured to influence the overall capacitance by altering the specified parameters.

Thus, according to an exemplary aspect shown in FIGS. 6A to 6C, a filter device 600 is provided that includes a bulk acoustic resonator having a substrate (e.g., substrate 120 of FIG. 1A), and a piezoelectric layer (e.g., layer 110 of FIG. 1A) coupled to the substrate by one or more intermediate layers (e.g., layer 124 of FIG. 1B). Moreover, a conductor pattern is provided on a surface of the piezoelectric layer that can include a pair of busbars (e.g., busbars 132 and 134 of FIG. 1A) having interleaved fingers extending therefrom to form the IDT. A dielectric capacitor 640 is then electrically coupled in series to the IDT of the bulk acoustic resonator and includes a dielectric layer 644 on a surface of one of the busbars (e.g., first busbar (e.g., 632A)) and at least one metal layer (e.g., metal layers 632B and/or 642B) on a surface of the dielectric layer 644 that is opposite the first busbar (e.g., 632A) to form the dielectric capacitor 640.

FIG. 7 is a top plan view of a portion of a filter device 700 that includes an XBAR with a pair of dielectric capacitors coupled in series according to an exemplary aspect. As described with respect to FIG. 6B, a dielectric capacitor 640 can be coupled in series to one of the busbars of the acoustic resonator. In the alternative aspect shown in FIG. 7, dielectric capacitors 740A and 740B are disposed on opposing sides of the IDT 730 of an acoustic resonator, which can correspond to IDT 130 of FIG. 1A as described above.

It should be appreciated that the two dielectric capacitors 740A and 740B generally have the same configuration as dielectric capacitor 640 described above with respect to FIG. 6A. Thus, in this aspect, the filter device 700 includes an additional dielectric capacitor electrically coupled in series to the bulk acoustic resonator. This additional capacitor also includes a dielectric layer on a surface of a second busbar (e.g., busbar 134 of FIG. 1A) of the pair of busbars and at least one metal layer on a surface of the dielectric layer opposite the second busbar to form the additional dielectric capacitor. According to this configuration, the bulk acoustic resonator (e.g., including IDT 730) is electrically coupled in series between the dielectric capacitor 740A (e.g., a first series capacitor) and the additional dielectric capacitor 740B (e.g., a second series capacitor).

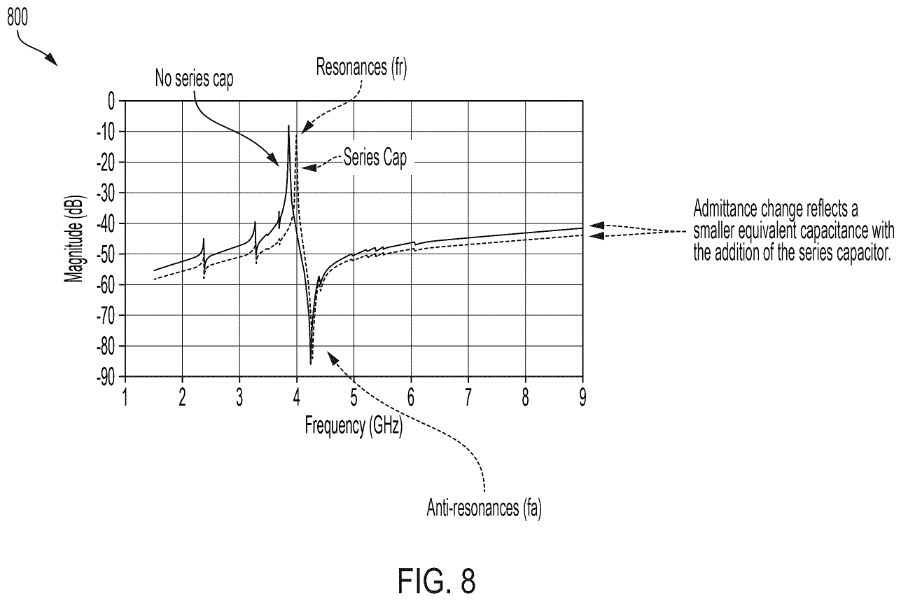

FIG. 8 is a chart of an admittance of a filter device with one or more acoustic resonators (e.g., XBARs) as a function of frequency with a dielectric capacitor coupled in series according to an exemplary aspect. More particularly, chart 800 shows the admittance in magnitude (dB) as a function of frequency (GHz) for the filter device comparing an acoustic resonator with a series capacitor according to the exemplary aspect and a filter device having an acoustic resonator with no series capacitor. The plot is simulated using finite element method (FEM) simulation techniques.

Specifically, the admittance plot 800 of FIG. 8 illustrates the reduced coupling achieved with the addition of the series capacitor. Moreover, the electromechanical coupling is defined as the frequency spacing between the resonance and anti-resonance. A reduction in this spacing equates to a reduction in coupling, thereby facilitating the design of narrower band filters. In this aspect, the admittance plot demonstrates two key resonances labeled as “resonances (fr)” and “anti-resonances (fa).” The plots indicate that the configuration without the series capacitor results in a different coupling behavior compared to the exemplary configuration having the series capacitor. As generally known to those skilled in the art, the definition of coupling is provided as:

$$Coupling = {k}_{eff}^{2} = \frac{{f}_{r}^{2} - {f}_{a}^{2}}{{f}_{a}^{2}} ,$$

which indicates the relationship between the resonant frequencies and the coupling factor. As illustrated in the plot 800 of FIG. 8, the admittance change reflects a smaller equivalent capacitance achieved through the addition of the series capacitor (e.g., dielectric capacitor 640 as described above).

In general, the equivalent capacitances can be evaluated at low and high frequencies using the modified Butterworth-Van Dyke (mBVD) model. At low frequency, a pair of capacitance values C₀ and Cₘ in parallel are provided with Lm representing the inductance of the circuit according to the mBVD model. In this aspect, the low-frequency behavior (e.g., the impedance) is defined by the equation (Z_{L}=jωL=2πfL), indicating the impedance of the inductor. As the frequency approaches zero, the impedance (Z_{L}) approaches zero, leading to the equivalent capacitance (C_{eg}=C₀+Cₘ), where C0 is the base capacitance and Cm represents the additional capacitance due to the mBVD structure. The high-frequency behavior is also analyzed, where the impedance is similarly defined, but as the frequency approaches infinity, (Z_{L}) approaches infinity. In this scenario, the equivalent capacitance simplifies to (C_{eq}=C₀), indicating that only the base capacitance is relevant at high frequencies. In this model the low-frequency circuit comprises a short circuit representation of Cₘ and the high-frequency circuit comprises an open circuit representation.

As also described above, the exemplary aspects utilize a dielectric capacitor coupled in series to an acoustic resonator. Using the mBVD model, at low frequency, the impedance (Z_{L}) is defined as (jωL=2πfL). As the frequency (f) approaches zero, the impedance (Z_{L}) approaches zero, leading to the equation

$$( \frac{1}{{C}_{eq}} = \frac{1}{{C}_{series}} + \frac{1}{( {C}_{0} + {C}_{m} )} ) .$$

This indicates that the equivalent capacitance is affected by both the series capacitor (Cₛₑᵣᵢₑₛ) and the sum of (C₀) and (Cₘ). In this aspect, the circuit configuration for the mBVD with a series capacitor, where (Lₘ) and (Cₘ) are in parallel to (C₀) and in series to (Cₛₑᵣᵢₑₛ). At high frequency, the impedance (Z_{L}) is similarly defined as (jωL=2πfL). As the frequency (f) approaches infinity, the impedance (Z_{L}) also approaches infinity. The equation for equivalent capacitance at this frequency is given as

$$( \frac{1}{{C}_{eq}} = \frac{1}{{C}_{series}} + \frac{1}{{C}_{0}} ) .$$

This reflects that at high frequencies, the equivalent capacitance is predominantly influenced by the series capacitor (Cₛₑᵣᵢₑₛ) and (C₀).

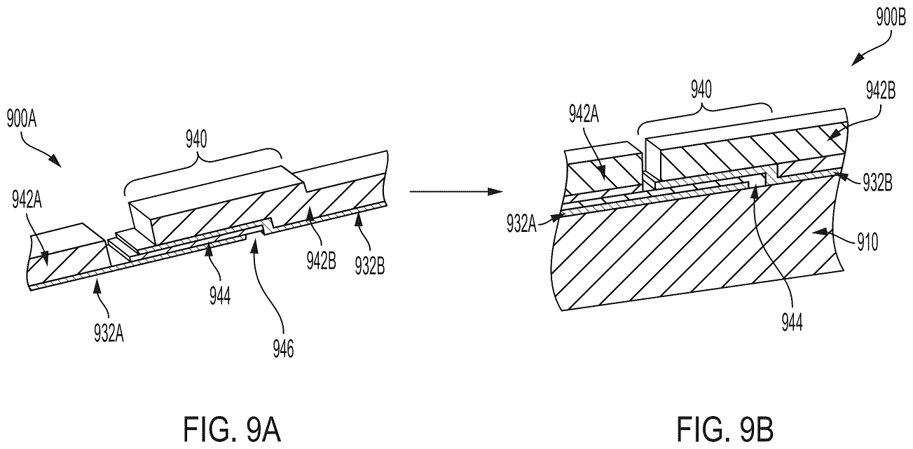

FIG. 9A is a schematic view of a portion of a filter device 900A that includes an acoustic resonator with a dielectric capacitor coupled in series according to another exemplary aspect. In general, the filter device 900A has a similar configuration as described above with respect to filter device 600 of FIG. 6A. That is, FIG. 9A is a schematic view of a portion of a filter device 900A that includes an acoustic resonator (e.g., an XBAR) with a dielectric capacitor 940 coupled in series according to an exemplary aspect. As shown in the partial view in FIG. 9A, a portion of metal pattern (e.g., referred to as metal 1 or M1) that can form a portion of a busbar 932A is shown, in which the busbar 932A can correspond to one of the pair of busbars 132 and 134 as shown in FIG. 1A, for example. Moreover, a second metal pattern 942A (e.g., referred to as metal 2 or M2) can be disposed on a surface of busbar 932A when forming the acoustic resonator device. As described above, metal layer M1 can also be a wire line or other metal layer extending from the busbar of the acoustic resonator.

As further shown in FIG. 9B, the at least one metal layer (i.e., metal layer 932B) can be disposed on a surface of a piezoelectric layer (e.g., piezoelectric layer 110 in FIG. 1A and shown as piezoelectric layer 910 in FIG. 9B), such that the at least one metal layer 932B is substantially coplanar with the first busbar 932A, which is also disposed on the surface of the piezoelectric layer 910. As noted above, the term “substantially” as used herein is used to describe when components, parameters and the like are generally the same taking into account minor variations due to manufacturing variances, for example. Thus, the term “substantially coplanar” in this context means coplanar or parallel and within ±10% of being coplanar or parallel according to an exemplary aspect.

As also shown in FIG. 9A, a gap 946 extends between the metal layer 932B and the metal layer 932A in a planar view of the surface of the piezoelectric layer 910. It is noted that the metal layer 932B can be formed by a same metal and metal deposition process as the metal layer 932A (which can be a portion of a busbar of the acoustic resonator) or can be formed by separate metal layers according to exemplary aspects. As also shown, one or more additional metal layers M2 (and numbered as metal layer 942B) can be disposed on metal layer 932B to provide a plurality of metal layers, which can also adjust the capacitance of dielectric capacitor 940 in an exemplary aspect. As further shown, filter device 600 has a gap between the metal layers 932A and 932B to prevent shorting the capacitor.

FIG. 9B illustrates a variation of the configuration of the filter device 900A shown in FIG. 9A in which the dielectric layer 944 further fills the gap 946 (shown in FIG. 9A) to be between the two metal layers M1 and M2 (i.e., metal layer 932A and 932B). In an exemplary aspect, the dielectric layer 944 can be formed by silicon oxide or silicon dioxide. Advantageously, this configuration enhances the capacitive properties of the filter device 900B. More particularly, a metal-oxide-metal cap structure is provided with a dielectric layer, such as silicon oxide, that effectively fill the gap 946 present between the metal layers. In this configuration the integrity and performance of the capacitor can be maintained to ensure that the electrical characteristics are optimized for the filter application.

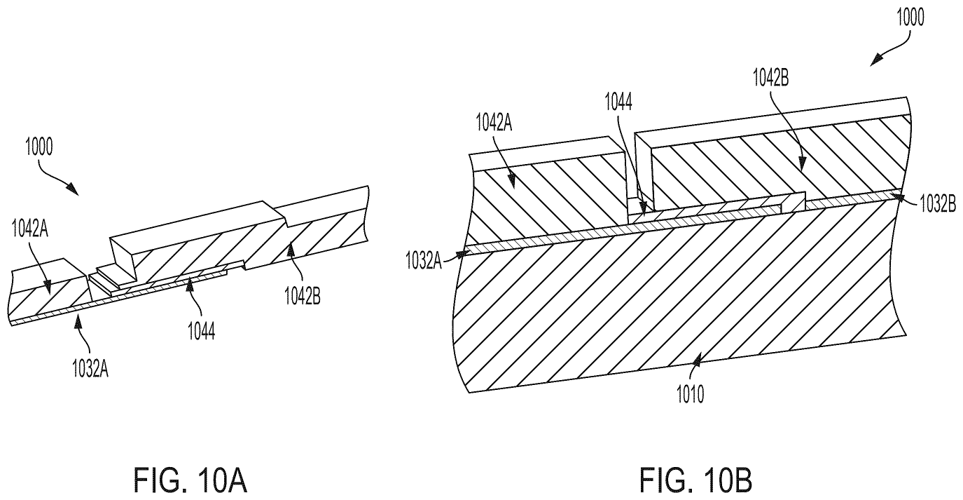

FIG. 10A is a schematic view of a portion of a filter device that includes an acoustic resonator with a dielectric capacitor coupled in series according to another exemplary aspect. FIG. 10B is a detailed schematic view of the portion of the filter device shown in FIG. 10A. In general, the filter device 1000 has a similar configuration as described above with respect to filter device 600 of FIG. 6A and filter device 900A/900B of FIGS. 9A and 9B. That is, FIGS. 10A and 10B are schematic view of a portion of a filter device 1000 that includes an acoustic resonator (e.g., an XBAR) with a dielectric capacitor coupled in series according to an exemplary aspect. As shown in the partial views, a portion of metal pattern (e.g., referred to as metal 1 or M1) forming a busbar 1032A is shown, in which the busbar 1032A can correspond to one of the pair of busbars 132 and 134 as shown in FIG. 1A, for example. In this exemplary aspect, busbar 1032A corresponds to a portion of busbar 132. As described above, metal layer M1 can also be a wire line or other metal layer extending from the busbar of the acoustic resonator. Moreover, a second metal pattern 1042A (e.g., referred to as metal 2 or M2) can be disposed on a surface of busbar 632A when forming the acoustic resonator device.

As described above, the at least one metal layer forming one of the electrodes of dielectric capacitor 640, for example, can be formed by a plurality of metal layers, such a metal layer 632B and 642B. Moreover, one or more (or all) of these layers can generally conform to a shape of the dielectric layer 644 in a plan view of the surface of the piezoelectric layer of the filter device. It should be appreciated that this conforming of the one or more layers can result from the deposition process of the one or more metal layers, for example. For example, the metal layers 632B and 642B may, at least partially, conform to the dielectric layer 644 in a thickness direction based on a thickness of the dielectric layer 644.

According to the exemplary aspects of FIGS. 10A and 10B, the metal layer 1042B can be deposited directly on the dielectric layer 1044. In other words, a first metal pattern (e.g., metal layer M1) that includes metal layer 1032A (i.e., forming a portion of the busbar of the acoustic resonator) and metal layer 1032B is formed on a surface of piezoelectric layer 1010, which can correspond to piezoelectric layer 110 of FIG. 1A as described above, for example. Moreover, a single metal pattern (e.g., metal layer M2) can be formed on each of the first metal layer M1 (including metal layers 1032A and 1032B) and the dielectric layer 1044. Otherwise, the configurations of the dielectric capacitor and filter device are similar to those discussed above with respect to FIGS. 6A to 6C, 7 and 9A-9B.

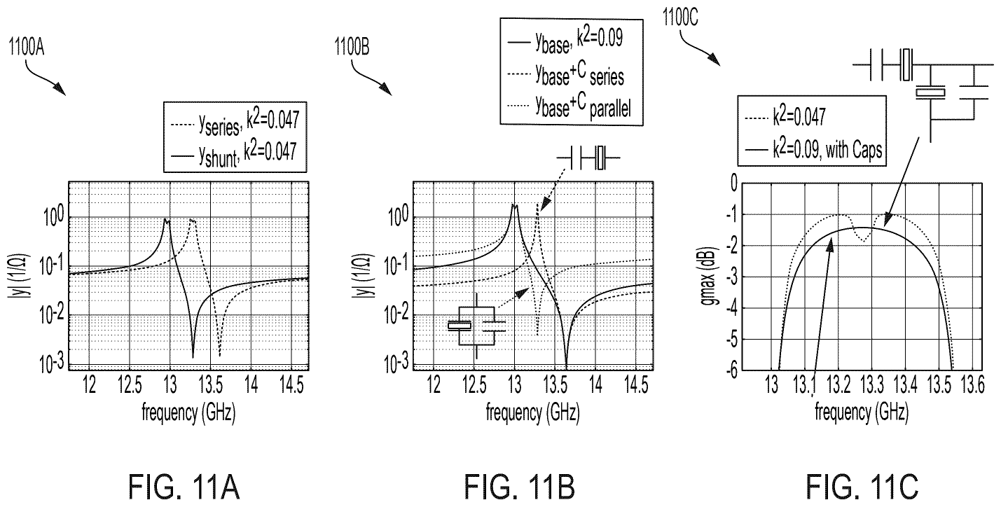

FIGS. 11A to 11C are charts of an admittance as a function of frequency of the filter device according to exemplary aspects. More particularly, the charts show the admittance as a function of frequency (GHz) for the filter device comparing an acoustic resonator with a series capacitor according to the exemplary aspect and a filter device having an acoustic resonator with no series capacitor. The plots are simulated using finite element method (FEM) simulation techniques.

In general, “spurious resonance” in series resonators causes loss in the passband, as illustrated by the plot 1100A in FIG. 11A. In the exemplary aspect, resonators are utilized that have roughly double the necessary coupling value k². As described herein, the addition of the dielectric capacitors in series allows for the decoupling of the resonators that effectively shifts the effects of spurious resonance below the passband. In FIG. 11B, a plot 1100B is provided that illustrates a capacitor is added in parallel with the shunt resonators, as indicated by the dotted line in the middle figure. Moreover, a series capacitor (e.g., a dielectric capacitor as described herein) is also introduced to the resonators in series, of which the effects are represented by the dashed line shifting the resonance frequency of the resonator upward (i.e., to the right). Finally, FIG. 11C provides a plot 1100C that illustrates a maximum available gain (gmax (dB), such as an ideal passband shape) for a typical ladder filter that is affected by spurious resonance (i.e., illustrated in the dotted line) compared to a similar filter device (e.g., a ladder circuit) that is configured with over-coupled resonators (i.e., the solid line) by utilizing the series capacitors described herein. As shown, the frequency response of the exemplary configuration (i.e., the solid line plot) shows the filter device is not affected by spurious resonance. In other words, the dotted line with no dielectric capacitor has a spur at the center of the passband, whereas this the spurious resonance is eliminated by the series capacitor as shown in the solid line.

Based on the foregoing disclosure, a filter device is provided that includes a plurality of a bulk acoustic resonator. Moreover, one or more of the bulk acoustic resonators can include a substrate; a piezoelectric layer coupled to the substrate by one or more intermediate layers; and an IDT on a surface of the piezoelectric layer. As described above, the IDT can include a pair of busbars (e.g., busbars 132 and 134 of FIG. 1A) having a plurality of interleaved fingers extending therefrom. In an exemplary aspect, the pair of busbars can extend in a first direction and the interleaved fingers can extend in a second direction that is substantially perpendicular to the first direction.

Moreover, a capacitor (e.g., a dielectric capacitor) is electrically coupled in series to the bulk acoustic resonator. The capacitor can be formed by a dielectric layer on a surface of a first busbar of the pair of busbars that is opposite the piezoelectric layer, and at least one metal layer on a surface of the dielectric layer that is opposite the first busbar. According to the exemplary aspect, the at least one metal layer is further disposed on the surface of the piezoelectric layer, such that the at least one metal layer is coplanar with the first busbar. A gap also extends between the at least one metal layer and the first busbar in a planar view of the surface of the piezoelectric layer. In an exemplary aspect, the gap extends in the first direction along a side surface of the first busbar that faces a side surface of the at least one metal layer, which is shown, for example, in the perspective view of FIG. 6A. The dielectric layer can be disposed in the gap as also described above.

Yet further, it is again noted that the dielectric capacitor can be implemented in series with an IDT of an acoustic resonator, such as the XBAR configurations described herein, including an XBAR having a cavity (e.g., FIGS. 1A, 1B, 2A-2D, 3A and/or 3B) or a solidly-mounted XBAR such as that shown in FIG. 2E and described above. Alternatively, the dielectric resonator can also be implemented with other types of SAW or BAW resonators. In either case, by implementing the dielectric busbar capacitor in series with such acoustic resonators, the resonant frequency of the resonator can be shifted up in frequency, reducing the coupling and enabling the design of a narrower band filters as described herein.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A filter device comprising:
an acoustic resonator including:
a substrate;
a piezoelectric layer coupled to the substrate by one or more intermediate layers; and
a conductor pattern on a surface of the piezoelectric layer, the conductor pattern including a pair of busbars having a plurality of interleaved fingers extending therefrom to form an interdigital transducer (IDT); and
a dielectric capacitor electrically coupled in series to the acoustic resonator, the dielectric capacitor including a dielectric layer on a surface of a first busbar of the pair of busbars and at least one metal layer on a surface of the dielectric layer, such that the dielectric layer is between the first busbar and the at least one metal layer to form the dielectric capacitor.

2. The filter device according to claim 1, wherein the first busbar is configured as a first electrode of the dielectric capacitor and the at least one metal layer is configured as a second electrode of the dielectric capacitor, such that the dielectric layer is sandwiched between the first and second electrodes.

3. The filter device according to claim 1, wherein the at least one metal layer is further disposed on the surface of the piezoelectric layer, such that the at least one metal layer is substantially coplanar with the first busbar, and wherein a gap extends between the at least one metal layer and the first busbar in a planar view of the surface of the piezoelectric layer.

4. The filter device according to claim 3, wherein:
the pair of busbars extend in a first direction and the interleaved fingers extend in a second direction that is substantially perpendicular to the first direction, and
wherein the gap extends in the first direction along a side surface of the first busbar that faces a side surface of the at least one metal layer.

5. The filter device according to claim 4, wherein the dielectric layer is silicon oxide and is also disposed in the gap between the at least one metal layer and the first busbar.

6. The filter device according to claim 1, wherein the at least one metal layer comprises a plurality of metal layers, and the at least one metal layer conforms to a shape of the dielectric layer in a plan view of the surface of the piezoelectric layer.

7. The filter device according to claim 1, further comprising an additional dielectric capacitor electrically coupled in series to the acoustic resonator, the additional capacitor including a dielectric layer on a surface of a second busbar of the pair of busbars and at least one metal layer on a surface of the dielectric layer opposite the second busbar to form the additional dielectric capacitor, such that the acoustic resonator is electrically coupled in series between the dielectric capacitor and the additional dielectric capacitor.

8. The filter device according to claim 1, wherein a portion of the piezoelectric layer forms a diaphragm that is over a cavity that extends at least partially in the one or more intermediate layers, the one or more intermediate layers comprising silicon oxide or silicon dioxide, and the dielectric capacitor does not overlap the cavity in a plan view of the piezoelectric layer.

9. The filter device according to claim 1, wherein the one or more intermediate layers comprise a Bragg mirror disposed between the piezoelectric layer and the substrate.

10. The filter device according to claim 1, wherein the IDT is configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved fingers of the IDT.

11. A filter device comprising:
an acoustic resonator including:
a substrate;
a piezoelectric layer coupled to the substrate by one or more intermediate layers;
an interdigital transducer (IDT) on a surface of the piezoelectric layer, the IDT including a pair of busbars having a plurality of interleaved fingers extending therefrom; and
a capacitor electrically coupled in series to the acoustic resonator and integrated as a portion of a first busbar of the pair of busbars, the capacitor and a pair of metal layers and a dielectric layer disposed therebetween.

12. The filter device according to claim 11, wherein the pair of metal layers of the capacitor comprise:
a first busbar of the pair of busbars that is opposite the piezoelectric layer; and
at least one metal layer on a surface of the dielectric layer that is opposite the first busbar.

13. The filter device according to claim 12, wherein the first busbar is configured as a first electrode of the capacitor and the at least one metal layer is configured as a second electrode of the capacitor.

14. The filter device according to claim 12, wherein the at least one metal layer is further disposed on the surface of the piezoelectric layer, such that the at least one metal layer is substantially coplanar with the first busbar, and wherein a gap extends between the at least one metal layer and the first busbar in a planar view of the surface of the piezoelectric layer.

15. The filter device according to claim 14, wherein:
the pair of busbars extend in a first direction and the interleaved fingers extend in a second direction that is substantially perpendicular to the first direction,
wherein the gap extends in the first direction along a side surface of the first busbar that faces a side surface of the at least one metal layer, and
the dielectric layer is silicon oxide and is also disposed in the gap between the at least one metal layer and the first busbar.

16. The filter device according to claim 12, wherein the at least one metal layer comprises a plurality of metal layers, and the at least one metal layer conforms to a shape of the dielectric layer in a plan view of the surface of the piezoelectric layer.

17. The filter device according to claim 12, further comprising:
an additional dielectric capacitor electrically coupled in series to the acoustic resonator, the additional capacitor integrated as a portion of a second busbar of the pair of busbars, the additional capacitor including a dielectric layer on a surface of a second busbar of the pair of busbars and at least one metal layer on a surface of the dielectric layer opposite the second busbar to form the additional dielectric capacitor, such that the acoustic resonator is electrically coupled in series between the dielectric capacitor and the additional dielectric capacitor,
wherein the additional capacitor is disposed substantially midway between the IDT of the acoustic resonator and another acoustic resonator of the filter device.

18. The filter device according to claim 11, wherein a portion of the piezoelectric layer forms a diaphragm that is over a cavity that extends at least partially in the one or more intermediate layers, the one or more intermediate layers comprising silicon oxide or silicon dioxide, and the capacitor does not overlap the cavity in a plan view of the piezoelectric layer.

19. The filter device according to claim 1, wherein the one or more intermediate layers comprise a Bragg mirror disposed between the piezoelectric layer and the substrate.

20. A radio frequency module comprising:
a filter device including a plurality acoustic wave resonators connected in parallel; and
a radio frequency circuit coupled to the filter device, the filter device and the radio frequency circuit being enclosed within a common package,
wherein at least one acoustic wave resonator of the plurality of acoustic wave resonators of the filter device includes:
a substrate;
a piezoelectric layer coupled to the substrate by one or more intermediate layers;
a conductor pattern on a surface of the piezoelectric layer, the conductor pattern including a pair of busbars having a plurality of interleaved fingers extending therefrom to form an interdigital transducer (IDT), and
wherein the filter device further includes a dielectric capacitor electrically coupled in series to the acoustic resonator, the dielectric capacitor including a dielectric layer on a surface of a first busbar of the pair of busbars and at least one metal layer on a surface of the dielectric layer, such that the dielectric layer is between the first busbar and the at least one metal layer to form the dielectric capacitor.
